(19) United States
(12) Patent Application Publication
(10) Pub. No.: US 2008/0009138 A1
(43) Pub. Date: Jan. 10, 2008

(54) METHOD FOR FORMING PATTERN OF A SEMICONDUCTOR DEVICE

(75) Inventor: Ki Lyoung Lee, Hwaseong-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/739,651

(22) Filed: Apr. 24, 2007

(30) Foreign Application Priority Data
Jul. 10, 2006 (KR) 10-2006-0064400

(51) Int. Cl. H01L 21/311

(52) U.S. Cl. 438/703; 257/E21.245

(57) ABSTRACT

A method for forming a pattern of a semiconductor device comprises sequentially forming a carbon-rich polymer, an antireflection film containing silicon, and a photoresist film over a semiconductor substrate. A double patterning process is then performed. The double patterning process may be a negative tone double patterning process or a positive tone double patterning process.

### CROSS-REFERENCE TO RELATED APPLICATIONS

The present application claims priority to Korean patent application number 10-2006-64400, filed on Jul. 10, 2006, which is incorporated by reference in its entirety.

### BACKGROUND OF THE INVENTION

1. Field of the Invention

The present invention relates to a method for forming a pattern of a semiconductor device, and more specifically, to a method for forming a pattern that overcomes resolution limits of a lithography process during the semiconductor fabricating process.

2. Description of the Related Art

It is difficult to form line/space patterns of 50 nm or less typically by a one-time exposure using 1.0 (or less) numerical aperture (NA) ArF exposure equipment. To improve resolution in a lithography process and increase a process margin, diversified research on double patterning is actively in process. Double patterning is a process where a wafer coated with a photoresist material is exposed using two masks, and then developed. It is mainly used for complicated patterns (not simple lines or contacts), or for an exposure of dense patterns and isolated patterns to increase the process margin. The double patterning process involves exposing and etching a first pattern to double its pattern period, and exposing and etching a second pattern having the same pattern period between them. Since the second mask and etching processes are performed after the first mask and etching processes, an overlay degree can be measured. In relation to this, defects like misalignment may be improved and a desired resolution can be obtained. However, the technique increases the number of additional processes thereby complicating semiconductor assembly.

The double patterning process can be performed in a negative tone or in a positive tone. Negative tone double patterning is a method for obtaining a desired pattern by forming a pattern in the first mask process and removing the same pattern in the second mask process. Positive tone double patterning is a method for obtaining a desired pattern by adding a pattern from the first mask process to a pattern from the second mask process.

FIG. 1a through FIG. 1e briefly illustrate a negative tone double patterning process according to a related art.

Referring first to FIGS. 1a and 1b, an amorphous carbon layer 12, a SiON layer 13, a poly hard mask layer 14, a first antireflection film 15, and a first photoresist film 16 are sequentially formed on a semiconductor substrate 11. By using a first exposure mask (not shown), a first region of the entire surface is exposed. The exposed first photoresist film 16 is then developed to form a first photoresist film pattern 16′. Since this is the negative tone double patterning, the resultant pattern has a narrow space portion. Using the first photoresist film pattern 16′ as an etching barrier film, the first antireflection film 15 and the poly hard mask layer 14 are etched to form a poly hard mask pattern 14′.

Referring to FIG. 1c, a second antireflection film 17 and a second photoresist film are sequentially formed over the poly hard mask pattern 14′. After that, a second region of the surface is exposed by a second exposure mask (not shown) such that the second region does not overlap with the first region. The second photoresist film is then developed to form a second photoresist film pattern 18′.

Referring to FIG. 1d, using the second photoresist film pattern 18′ as an etching barrier film, the second antireflection film 17 and the poly hard mask pattern 14′ are etched to form a poly hard mask pattern 14″.

Referring to FIG. 1e, using the poly hard mask patter 14″ as an etching barrier film, the underlying SiON layer 13 and amorphous carbon layer 12 are etched to form a desired fine pattern.

FIG. 2a through FIG. 2e diagrammatically outline a positive tone double patterning process according to a related art.

Referring first to FIGS. 2a and 2b, an amorphous carbon layer 22, a SiON layer 23, a poly hard mask layer 24, a first antireflection film 25, and a first photoresist film 26 are sequentially formed on a semiconductor substrate 21. Using a first exposure mask (not shown), a first region of the surface is exposed. The exposed first photoresist film 26 is then developed to form a first photoresist film pattern 26′. Since this is the positive tone double patterning, the resultant pattern has a narrow line portion. Using the first photoresist film pattern 26′ as an etching barrier film, the first antireflection film 25 and the poly hard mask layer 24 are etched to form a poly hard mask pattern 24′.

Referring to FIG. 2c, a second antireflection film 27 and a second photoresist film are sequentially formed on the poly hard mask pattern 24′. After that, a second region of the surface is exposed by a second exposure mask (not shown) such that the second region does not overlap with the first region. The second photoresist film is then developed to form a second photoresist film pattern 28′.

Referring to FIG. 2d, using the second photoresist film pattern 28′ as an etching barrier film, the second antireflection film 27 is etched to form an antireflection film pattern 27′.

Referring to FIG. 2e, using the poly hard mask patter 24′ and the antireflection film pattern 27′ as an etching barrier film, the underlying SiON layer 23 and amorphous carbon layer 22 are etched to form a desired fine pattern.

In the negative- and positive-tone double patterning processes, the poly hard mask used as an etching barrier film of underlying materials should have a thickness of 1,000 Å or greater in consideration of its etching selectivity ratio to an underlying layer. Therefore, a typically used composition for the conformal antireflection film cannot form, on the poly hard mask layer, an antireflection film at a coating thickness of 1.0% or lower of substrate reflectivity. Moreover, instead of a structure using a poly-silicon, tungsten, nitride or oxide hard mask as a barrier as in the related art, the structure using SiON/amorphous carbon layer has to be used. Since both the negative- and positive-tone double patterning processes require additional processes including amorphous carbon layer deposition, bevel etching, SiON deposition, and etching, the overall process becomes complicated and manufacturing costs are increased by the application of chemical vapor deposition (CVD). In addition, because two masks are used for each wafer, throughput is deteriorated. When a pattern close to the resolution limit is formed in a cell area, the decreased design rule results in overlapping aerial images, thereby making it difficult to obtain a desired resolution. Misalignment caused by an error in mask arrangement may occur.

### SUMMARY OF THE INVENTION

The present invention provides a method for forming a pattern of a semiconductor device, which comprises a double patterning process using an antireflection film containing silicon and a carbon-rich polymer layer.

According to the method for forming a pattern of a semiconductor device, a carbon-rich polymer layer, an antireflection film containing silicon, and a photoresist film are sequentially deposited over a semiconductor substrate, and then a double patterning process is performed. The patterning process can be either a negative- or a positive-tone double patterning process.

Throughout the specification, “an antireflection film containing silicon” contains a sufficient amount of silicon, and functions as a hard mask for improving an etching selectivity ratio and, at the same time, as a bottom antireflection film that contains absorbent material at a 193 nm ArF wavelength for improving pattern uniformity. The antireflection film containing silicon is dry-etched with CF₄ gas, and can be removed by a special wet chemical. In addition, “carbon-rich polymer” is a substance having a carbon content of 80% or higher by weight, and is a known substitute for the amorphous carbon layer. Antireflection film and carbon-rich polymer exhibit excellent self-planarization features. Furthermore, since both the antireflection film containing silicon and the carbon-rich polymer layer are formed by a spin coating process, manufacturing costs decrease and the turn-around time (TAT) can be reduced.

### BRIEF DESCRIPTION OF THE DRAWINGS

The invention will be described in detail with reference to the following drawings in which like reference numerals refer to like elements, and wherein:

FIG. 1a through FIG. 1e are cross-sectional views, each diagrammatically outlining a negative tone double patterning process according to a related art;

FIG. 2a through FIG. 2e are cross-sectional views, each diagrammatically outlining a positive tone double patterning process according to a related art;

FIG. 3a through FIG. 3h are cross-sectional views, each diagrammatically outlining a negative tone double patterning process in a method for forming a pattern according to the present invention; and

FIG. 4a through FIG. 4g are cross-sectional views, each diagrammatically outlining a positive tone double patterning process in a method for forming a pattern according to the present invention.

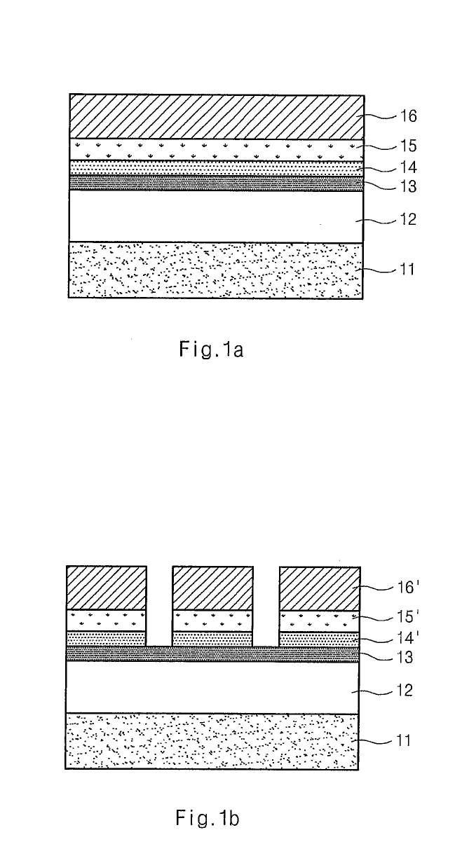

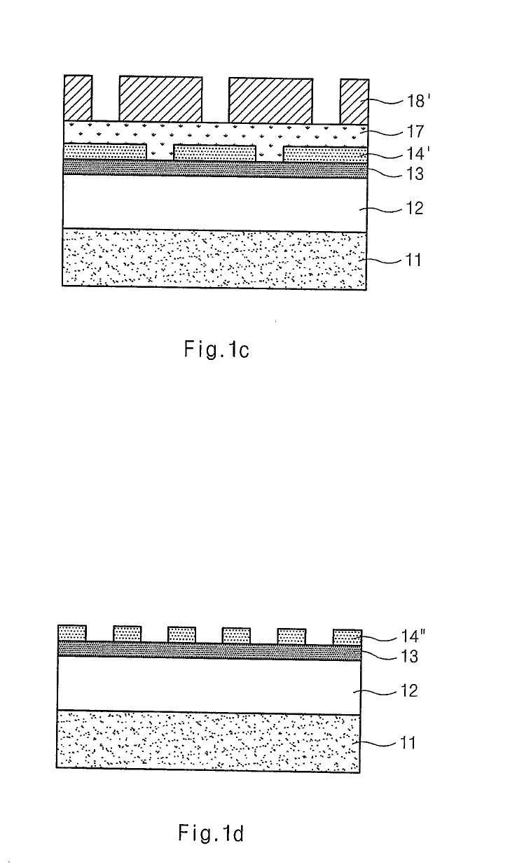

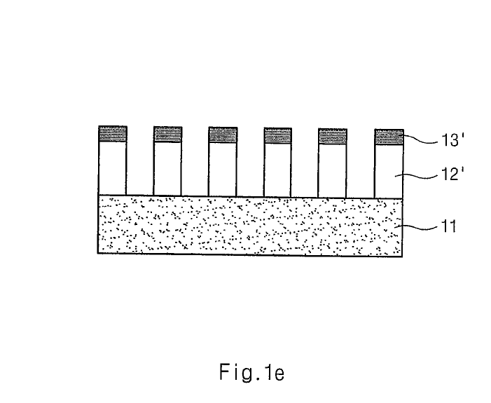

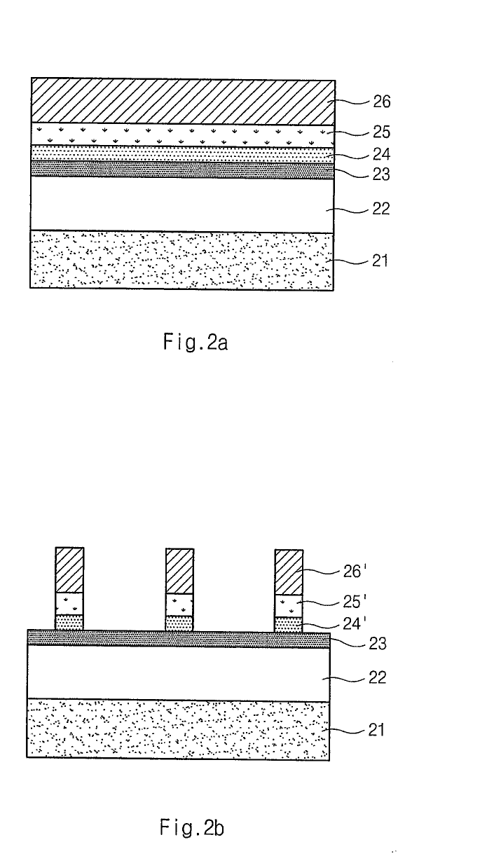

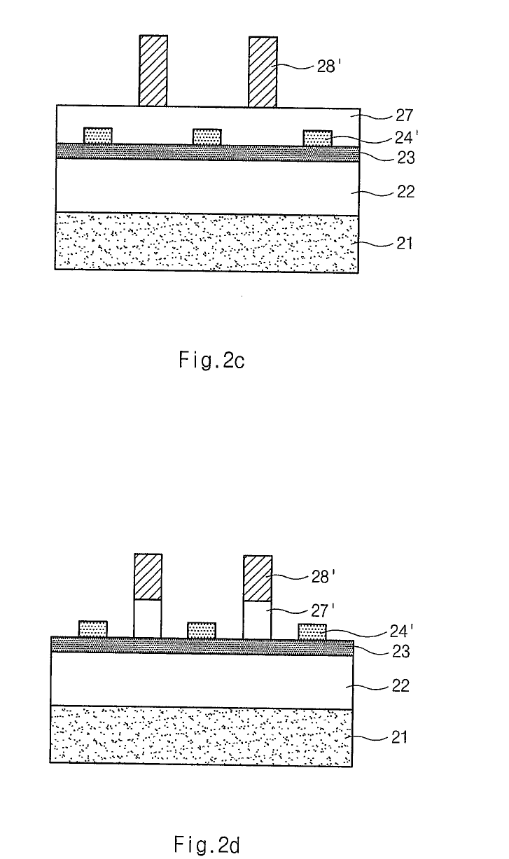

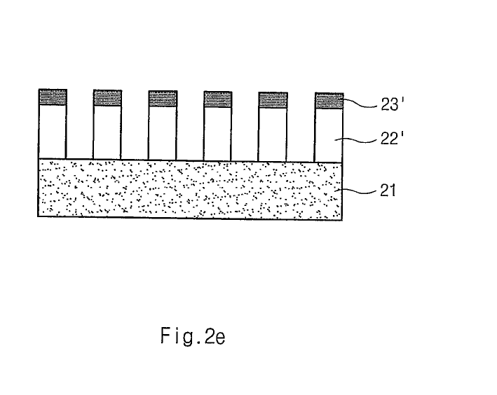

### DETAILED DESCRIPTION OF THE PREFERRED EMBODIMENTS

The invention will be described in detail with reference to the following drawings.

A negative tone double patterning process is used in a method for forming a pattern of a semiconductor device of the invention. An underlying layer, a carbon-rich polymer layer, a first antireflection film containing silicon, and a first photoresist film are sequentially formed over a semiconductor substrate. The first photoresist film is exposed and developed to form a first photoresist film pattern. The first antireflection film and the carbon-rich polymer layer are etched using the first photoresist film pattern as an etching barrier film to form a first carbon-rich polymer layer pattern. A second antireflection film and a second photoresist film are sequentially formed over the first carbon-rich polymer layer pattern. A region not overlapping with the first antireflection film pattern is exposed and developed to form a second photoresist film pattern. The second antireflection film and the first carbon-rich polymer layer pattern are etched using the second photoresist film pattern as an etching barrier film to form a second carbon-rich polymer layer pattern. Antireflection film materials deposited between the second carbon-rich polymer layer patterns are removed. An underlying layer is etched using the second carbon-rich polymer layer pattern as an etching barrier film to form an underlying layer pattern.

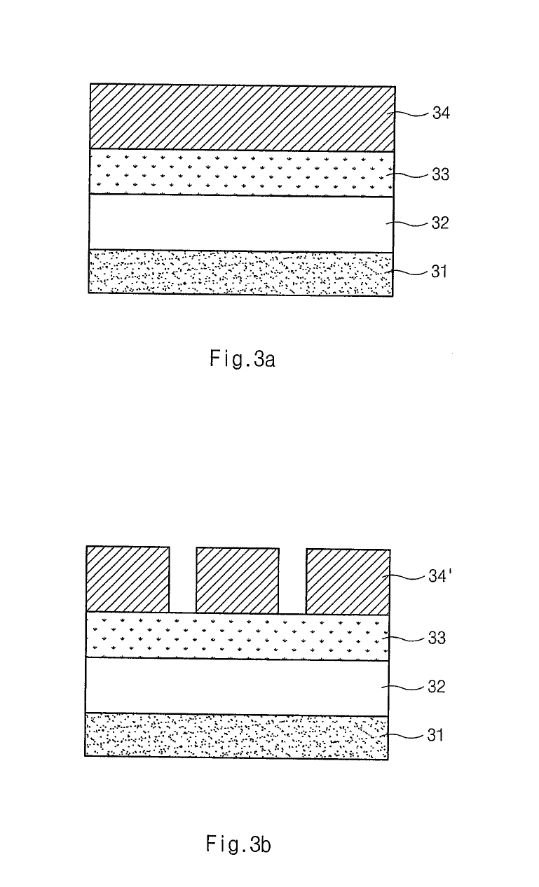

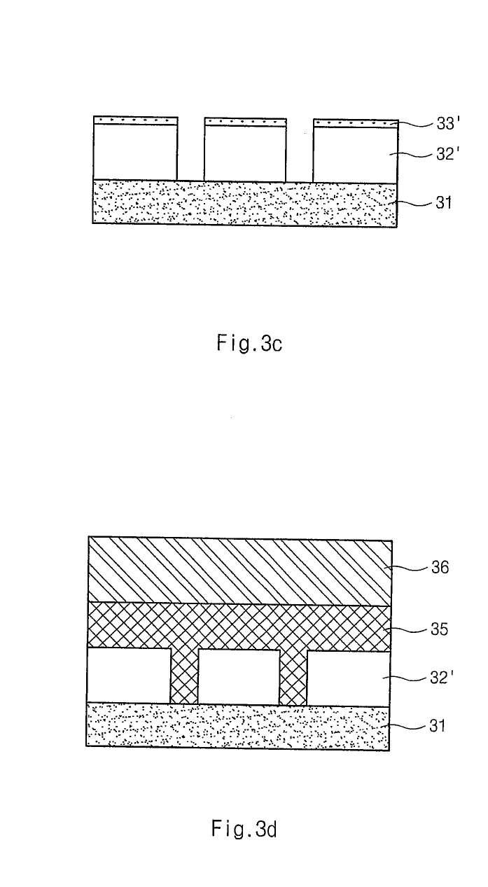

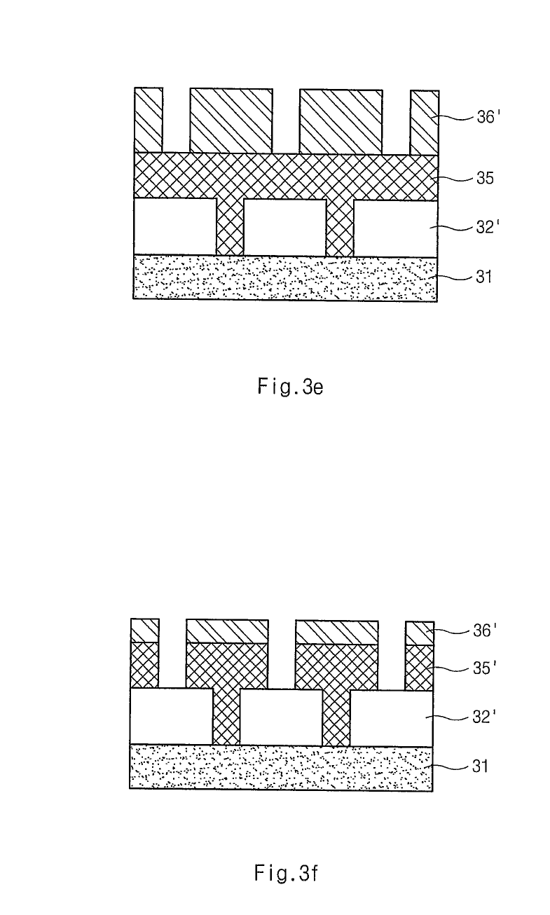

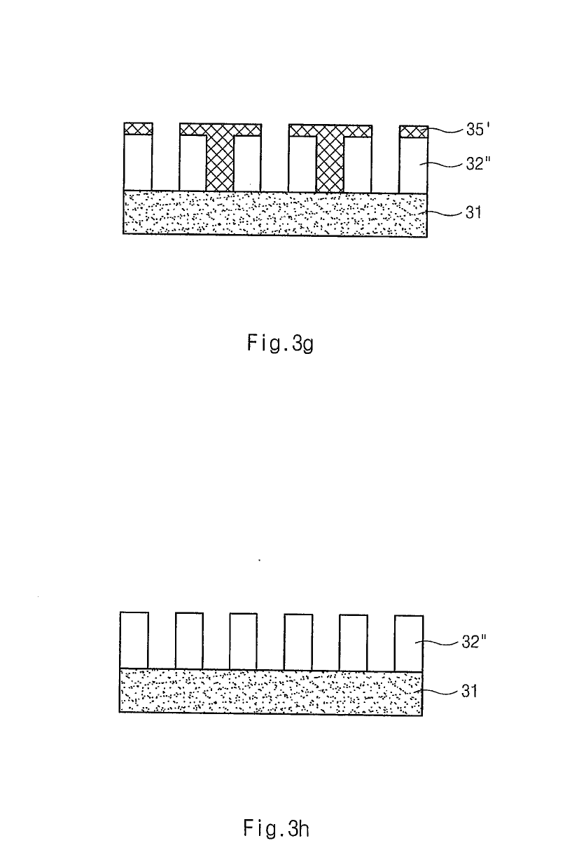

FIG. 3a through FIG. 3h illustrate a negative tone double patterning process in the method for forming a pattern of a semiconductor device according to the present invention.

Referring to FIGS. 3a and 3b, a carbon-rich polymer layer 32 and a first antireflection film containing silicon 33, each having a proper thickness for ensuring an etching selectivity ratio, are formed over a semiconductor substrate 31. In one embodiment, the semiconductor substrate 31 is formed with silicon nitride based material. A first photoresist film 34 is formed on the resultant upper surface. In one embodiment, a spin on coating process is employed for deposition of the carbon-rich polymer layer 32 and the first antireflection film 33. By using a first exposure mask (not shown), a first region of the surface is exposed. The exposed first photoresist film 34 is then developed to form a first photoresist film pattern 34′. Since this is the negative tone double patterning, the resultant pattern has a narrow space portion and the pattern is formed such that the pattern period is doubled.

Referring to FIG. 3c, using the first photoresist film pattern 34′ as an etching barrier film, the underlying first antireflection film 33 is etched to form a first antireflection film pattern 33′. Using the first antireflection film pattern 33′ as an etching barrier film, the underlying carbon-rich polymer layer 32 is etched to form a first carbon-rich polymer layer pattern 32′. Etching gases for the first antireflection film 33 include, but are not limited to, CF₄ and O₂, either alone or in combination. Meanwhile, etching gases for the carbon-rich polymer layer 32 include, but are not limited to, O₂, N₂, and H₂, either alone or in combination. When the carbon-rich polymer layer etching is completed, some of the first antireflection film pattern 33′ may remain on the first carbon-rich polymer layer pattern 32′.

Referring to FIGS. 3d and 3e, after selectively removing the first antireflection film pattern 33′ by a special wet chemical or without removing the first antireflection film pattern 33′, a second antireflection film 35 containing silicon and a second photoresist film 36, each having an appropriate thickness for ensuring an etching selectivity ratio, are sequentially deposited over the first carbon-rich polymer layer pattern 32′. After that, a second region of the surface is exposed by a second exposure mask (not shown) such that the second region does not overlap with the first region. The second photoresist film 36 is then developed to form a second photoresist film pattern 36′.

Referring to FIGS. 3f and 3g, using the second photoresist film pattern 36′ as an etching barrier film, the underlying second antireflection film 35 is etched to form a second antireflection film pattern 35′. Using the second antireflection film pattern 35′ as an etching barrier film, the underlying first carbon-rich polymer layer pattern 32′ is etched to form a second carbon-rich polymer layer pattern 32″. Etching gases for the second antireflection film 35 include, but are not limited to, CF₄ and O₂, either alone or in combination. Meanwhile, etching gases for the first carbon-rich polymer layer pattern 32′ include, but are not limited to, O₂, N₂, and H₂, either alone or in combination.

Finally, referring to FIG. 3h, the antireflection film deposited between the patterns from the exposure and etching processes of the first region is removed by a compound serving as an antireflection film removing agent. Examples of the compound include, but are not limited to, fluorine, alkaline compounds, and mixtures thereof. After that, using the second carbon-rich polymer layer pattern 32″ as an etching barrier layer, base material (e.g., silicon nitride) is etched.

A positive tone double patterning process is used in a method for forming a pattern of a semiconductor device of the invention. An underlying layer, a first carbon-rich polymer layer, a first antireflection film containing silicon, and a first photoresist film are sequentially formed over a semiconductor substrate. The first photoresist film is exposed and developed to form a first photoresist film pattern. The first antireflection film is etched using the first photoresist film pattern as an etching barrier film to form a first antireflection film pattern. A second carbon-rich polymer layer, a second antireflection film containing silicon and a second photoresist film are sequentially formed over the first antireflection film pattern. A region that does not overlap with the first antireflection film pattern is exposed and developed to form a second photoresist film pattern. The second antireflection film is etched using the second photoresist film pattern as an etching barrier film to form a second antireflection film pattern. The first and second carbon-rich polymer layers are etched simultaneously using the first and second antireflection film pattern as etching barrier films to form a carbon-rich polymer pattern. An underlying layer is etched using the carbon-rich polymer layer as an etching barrier film to form an underlying layer pattern.

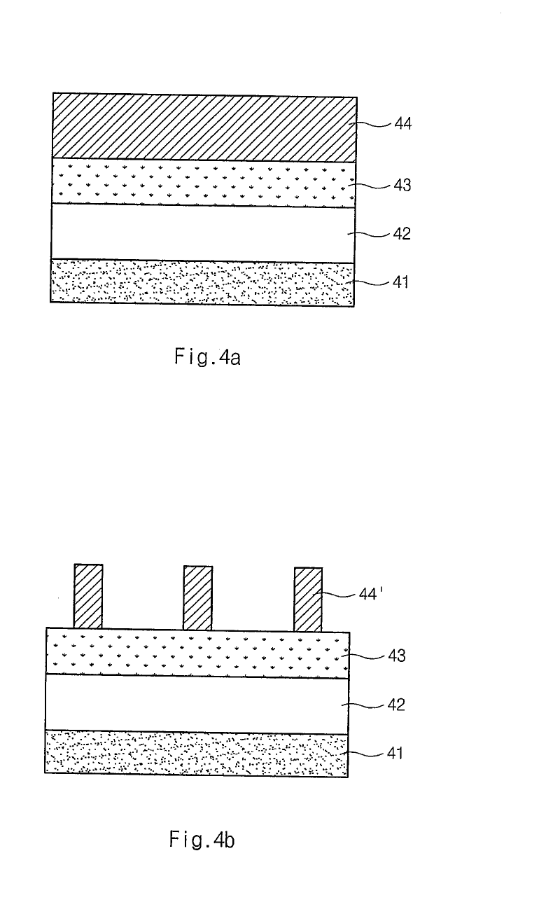

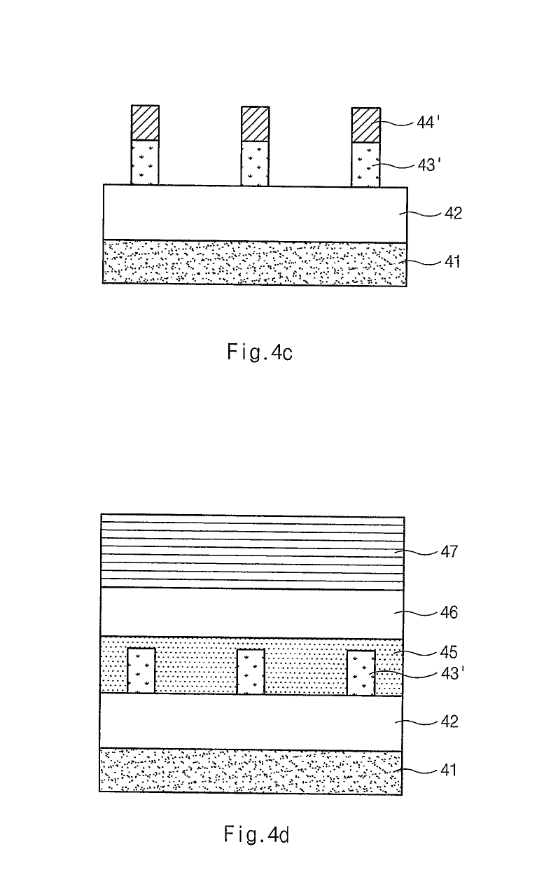

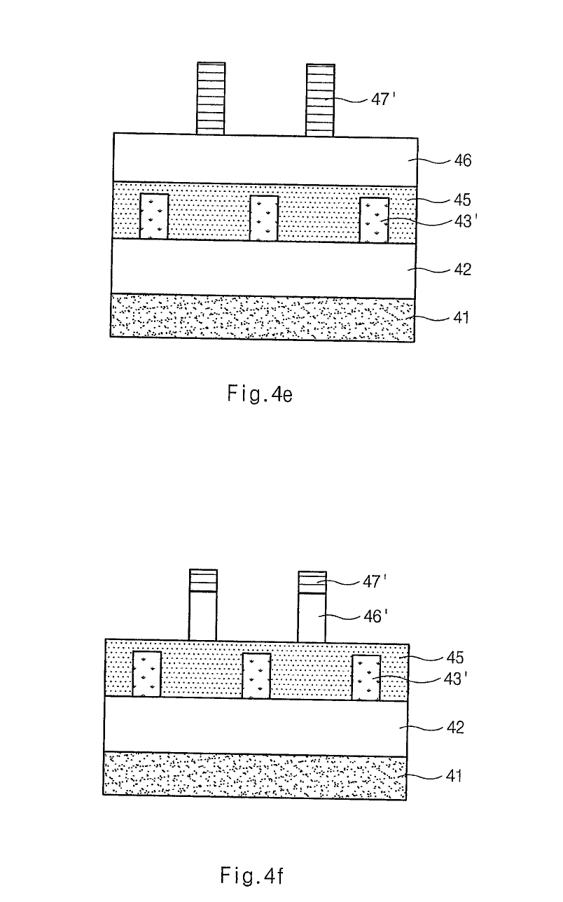

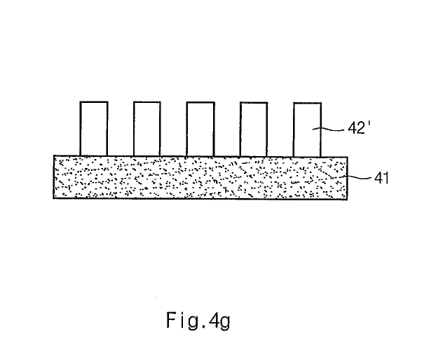

FIG. 4a through FIG. 4g illustrate a positive tone double patterning process in the method for forming a pattern of a semiconductor device according to the invention.

Referring to FIGS. 4a and 4b, a first carbon-rich polymer layer 42 and a first antireflection film containing silicon 43, each having a proper thickness for ensuring an etching selectivity ratio, are formed on an upper portion of a semiconductor substrate 41. In one embodiment, semiconductor substrate 41 is formed of silicon nitride based material. A first photoresist film 44 is deposited on the resultant upper surface. In one embodiment, a spin on coating process is employed for deposition of the first carbon-rich polymer layer 42 and the first antireflection film 43. Using a first exposure mask (not shown), a first region of the surface is exposed. The exposed first photoresist film 44 is then developed to form a first photoresist film pattern 44′. Since this is the positive tone double patterning, the resultant pattern has a narrow line portion and the pattern is formed such that the pattern period is doubled.

Referring to FIG. 4c, using the first photoresist film pattern 44′ as an etching barrier film, the underlying first antireflection film 43 is etched to form a first antireflection film pattern 43′, and the remaining photoresist film is removed with thinner. Since the antireflection film 43 containing silicon and the carbon-rich polymer layer 42 are generally cross-linked by baking at a temperature of 200° C. or higher, which is higher than the bake temperature of a photoresist, they are not removed with thinner. For etching the first antireflection film 43, CF₄ and O₂ are used either alone or in combination.

Referring to FIGS. 4d and 4e, a second carbon-rich polymer layer 45, a second antireflection film containing silicon 46, and a second photoresist film 47 are sequentially formed over the first antireflection film pattern 43′. After that, a second region of the surface is exposed by a second exposure mask (not shown) such that the second region does not overlap with the first region. The second photoresist film 47 is developed to form a second photoresist film pattern 47′. The carbon-rich polymer exhibits an excellent self-planarization feature such that it is evenly coated over the first antireflection film pattern 43′.

Referring to FIG. 4f, using the second photoresist film pattern 47′ as an etching barrier film, the underlying second antireflection film 46 is etched to form a second antireflection film pattern 46′. For etching the second antireflection film 46, CF₄ and O₂ are used either alone or in combination.

Finally, referring to FIG. 4g, using the second antireflection film pattern 46′ as an etching barrier film, the underlying carbon-rich polymer layers 42 and 45 are etched to form a carbon-rich polymer layer pattern 42′. For etching the carbon-rich polymer layers 42 and 45, O₂, N₂ and H₂ may be used either alone or in combination. At this time, the thicknesses of the carbon-rich polymer layers 42 and 45 to be etched are high. Therefore, from the aspect of an etching selectivity ratio, there is a possibility that the second antireflection film pattern 46′ is completely removed and the exposed carbon-rich polymer layers 42 and 45 are etched. However, a critical dimension (CD) is determined in the process shown in FIG. 4f. Although the carbon-rich polymer layers 42 and 45 may be etched, the CD is not going to be changed. Later, the base material (e.g. silicon nitride) is etched using the carbon-rich polymer layer pattern 42′ as an etching barrier film.

Accordingly, the method for forming a pattern of the present invention is advantageous for forming patterns under resolution limits of exposure equipment with ease by employing the double patterning process. Moreover, by using the carbon-rich polymer that exhibits an excellent self-planarization feature and by using the antireflection film containing silicon capable of functioning as a hard mask to improve the etching selectivity ratio and at the same time, increasing the pattern uniformity, manufacturing costs decrease and turn-around time (TAT) can be reduced.

Although the preferred embodiment of the present invention has been described, it will be understood by those skilled in the art that the present invention should not be limited to the described preferred embodiment, but various changes and modifications can be made within the spirit and scope of the present invention as defined by the appended claims.

What is claimed is:

1. A method for forming a pattern of a semiconductor device, comprising the steps of:
sequentially forming an underlying layer, a carbon-rich polymer layer, a first antireflection film containing silicon, and a first photoresist film over a semiconductor substrate;
exposing and developing the first photoresist film to form a first photoresist film pattern;
etching the first antireflection film and the carbon-rich polymer layer by using the first photoresist film pattern as an etching barrier film to form a first carbon-rich polymer layer pattern;
sequentially forming a second antireflection film and a second photoresist film over the first carbon-rich polymer layer pattern;
exposing and developing a region that does not overlap with the first antireflection film pattern to form a second photoresist film pattern;
etching the second antireflection film and the first carbon-rich polymer layer pattern using the second photoresist film pattern as an etching barrier film to form a second carbon-rich polymer layer pattern;
removing antireflection film materials between the second carbon-rich polymer layer patterns; and
etching an underlying layer using the second carbon-rich polymer layer pattern as an etching barrier film to form an underlying layer pattern.

2. The method of claim 1, wherein etching the antireflection film is performed using CF₄ gas, O₂ gas, or both.

3. The method of claim 1, wherein etching the carbon-rich polymer layer is performed using O₂ gas, N₂ gas, H₂ gas, or combinations thereof.

4. The method of claim 1, wherein the antireflection film materials between carbon-rich polymer patterns are removed with fluorine, an alkaline compound, or both.

5. A method for forming a pattern of a semiconductor device, comprising the steps of:
sequentially forming an underlying layer, a first carbon-rich polymer layer, a first antireflection film containing silicon, and a first photoresist film over a semiconductor substrate;
exposing and developing the first photoresist film to form a first photoresist film pattern;
etching the first antireflection film using the first photoresist film pattern as an etching barrier film to form a first antireflection film pattern;
sequentially forming a second Carbon-rich polymer layer, a second antireflection film containing silicon and a second photoresist film over the first antireflection film pattern;
exposing and developing a region that does not overlap with the first antireflection film pattern to form a second photoresist film pattern;
etching the second antireflection film using the second photoresist film pattern as an etching barrier film to form a second antireflection film pattern;
etching the first and second carbon-rich polymer layer simultaneously using the first and second antireflection film pattern as an etching barrier film to form a carbon-rich polymer pattern; and
etching an underlying layer using the carbon-rich polymer layer as an etching barrier film to form an underlying layer pattern.

6. The method of claim 5, wherein etching the antireflection film is performed using CF₄ gas, O₂ gas, or both.

7. The method of claim 5, wherein etching the carbon-rich polymer layer is performed using O₂ gas, N₂ gas, H₂ gas, or combinations thereof.
